(19) United States
(12) Patent Application Publication
(10) Pub. No.: US 2003/0041301 A1
(43) Pub. Date: Feb. 27, 2003

(54) Apparatus and method of inspecting error in system board

(76) Inventors: Dong Wan Ryoo, Taejon (KR); Jeun Woo Lee, Taejon (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 09/981,744

(22) Filed: Oct. 19, 2001

(30) Foreign Application Priority Data
Aug. 22, 2001 (KR) 2001-50775

(51) Int. Cl. H04L 1/22; H04B 1/74; H02H 3/05; H05K 10/00; H03K 19/003; G06F 11/08

(52) U.S. Cl. 714/797

(57) ABSTRACT

Disclosed is an apparatus and method for error detection in a precise system board requiring reliability and safety for controlling a number of processes, in which a failure detector and maintainer is connected to the system board, so as to detect a failure of the system board and normally maintain the operation of the system board even in failure. The failure detector and maintainer is constituted by a single chip and connected to the system board to diagnose the failure and maintain the operation, and comprises a voter for judging signals received from the system board using an at least 2/4 simultaneous generation logic to output an output signal; a comparator for comparing signals from four channels of the system board to recognize a channel outputting a failure signal; and a detector for detecting the failure signal to execute a feedback signal for maintaining the operation of the system board, by which the signal from the detector is re-transmitted to the voter through an OR gate so that the operation of the system board can be maintained normal.

### BACKGROUND OF THE INVENTION

1. Field of the Invention

The present invention relates to an apparatus and method for failure detection and maintenance in a system board, and more particularly, to an apparatus and method for error detection in a precise system board requiring reliability for controlling a number of processes, in which a failure detector and maintainer is connected to the system board, so as to detect a failure of the system board and normally maintain the operation of the system board even in failure thereby enhancing the reliability and safety of the system board.

2. Description of the Related Art

Generally, in an important system such as a factory automation system or home automation system, the reliability of the system is enhanced through the increase of redundancy by using a voter in order to prevent fatal loss due to abrupt stop of the systems.

Meanwhile, redundancy is a value for indicating the degree of preparation of means that is, in transferring information, at least the required amount according to the amount of information. As the value of redundancy is larger, the probability of stop of the operation due to failure is lowered.

A conventional Korean Registered Patent No. 39064 entitled “Method of Failure Detection of Microprocessor” discloses a method of failure detection, in which a clock is oscillated in a certain period and inputted into a microprocessor for failure detection, and a failure condition is displayed while a failed condition alarming signal is outputted.

Also, another Korean Registered Patent No. 169808 entitled “Expert System for Failure Detection and Method of Failure Diagnosis” enables preceding failure diagnosis information to be case-established into a database for enhancing the reliability of failure diagnosis results, and includes steps of: comparing established present failure cases to the preceding failure diagnosis information to search the most similar case in the preceding failure cases; and judging if the present failure cases will be registered to the preceding failure cases.

Further, other Korean Registered Patent No. 15184 entitled “Safety System of Nuclear Reactor” discloses a safety system of a nuclear reactor which includes converters for measuring a number of parameters in the operation of the reactor, by which calculation is processed as respectively connected in parallel to each converter for measuring one parameter in the operation of the nuclear reactor and about a function of the parameters of the nuclear reactor indicating percentage of the whole load.

FIG. 1 schematically shows a conventional apparatus in which a system board 10 requiring reliability is connected to a voter 11, and description thereof will be made as follows.

The apparatus is comprised of the system board 10 for controlling the operation of the overall system; and the voter 11 for judging signals inputted from a number of channels of the system board 10 to execute the operation.

The voter 11 judges the operation through recognition of high or low signals from the four channels A to D in the system board 10, and when at least two of the four channels transmit high signals, confirms the corresponding signals and transmits the same to an output terminal. If 2, 3 or 4 high signals are inputted from the terminals of the channels A to B, the voter 11 recognizes the corresponding signals and transmits the same to the output terminal. On the other hand, if the high signal is inputted to one channel, the voter 11 neither recognizes the high signal nor transmits the corresponding signal to the output terminal.

According to the prior art, the operation of the system board 10 can be primarily maintained when the at least two normal signals of the four signals are outputted from the four channels by using the voter 11. However, if the normal signals are not outputted from the at least two channels, there is a problem that loss is generated due to the malfunction of the system board 10 for controlling the overall process.

As described above, in the system maintaining the operation with a redundancy by using the voter 11 according to a conventional voting mechanism, when the system board 10 has a failure and the various channels generate failure signals, the operation cannot be maintained for a certain time period so that the system board 10 may malfunction. The malfunction may cause a fatal effect to the control of the overall process and generate a great loss due to stop of the operation.

### SUMMARY OF THE INVENTION

Accordingly, the present invention has been proposed to solve the foregoing problems and it is an object of the invention to provide an apparatus and method of inspecting errors in a system board requiring reliability and safety, in which a failure detector and maintainer is connected to the system board to diagnose failure occurrence and maintain the operation of the system board. The failure detector and maintainer is comprised of a voter for judging signals received from the system board using an at least 2/4 simultaneous generation logic to output an output signal; a comparator for comparing signals from four channels of the system board to recognize a channel outputting a failure signal; and a detector for inputting the signal from the failed channel simultaneously with a feedback signal to a logic circuit to normally maintain the operation, by which the system board is normally maintained even if a failure occurs in operation thereof so that the safety and reliability thereof can be enhanced.

### BRIEF DESCRIPTION OF THE DRAWINGS

In the accompanying drawings:

FIG. 1 schematically shows an apparatus for controlling the operation of a system board using a voter of the prior art;

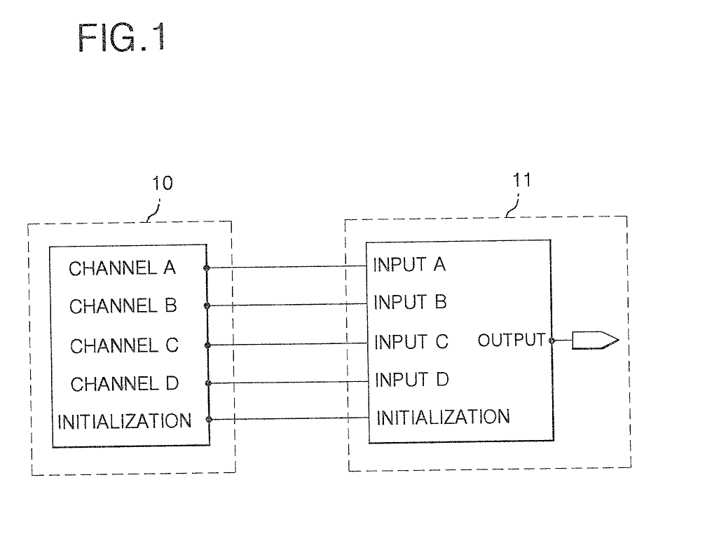

FIG. 2 schematically shows a failure detector and maintainer for controlling the operation of a system board of the invention; and

FIG. 3 is a flow chart of the failure detector and maintainer of the invention.

### DETAILED DESCRIPTION OF THE PREFERRED EMBODIMENT

The invention for obtaining the foregoing object is characterized by an apparatus for inspecting errors in a system board including a number of channels for controlling the overall operation of a system, comprising: means for judging signals respectively received in the number of channels of the system board; means for comparing the signals respectively received in the number of channels of the system board to output signals respectively informing if the channels are failed or not; and means for respectively transmitting normal signals to the failed channels, which are respectively inputted by the comparing means, to maintain the operation of the system board.

The invention is characterized in that the judging means comprises: a bypass terminal for separating a signal of the failed channel when interruption of the signal is required due to repair of the failed channel in the system board; and a manual trip terminal capable of forcibly changing the output value of the judging means to convert the operation, and the comparing means compares the input signals in the channels of the system board, and if a channel outputs a signal different from the other channels, outputs a signal informing that the channel outputting the different signal is failed.

Also, the invention is characterized by a method of inspecting errors in a system board, comprising the following steps of: receiving output signals in a voter from a number of channels of the system board; receiving the output signals in a comparator simultaneously with the voter from the number of channels of the system board to compare the output signals; comparing the output signals to output a signal informing that a channel outputting a signal different from the other channels is failed; and transmitting and logic-combining a feedback signal simultaneously with the output signal of the failed channel to input a normal signal to the voter.

Hereinafter, detailed description will be made about an embodiment of the invention in reference to the accompanying drawings.

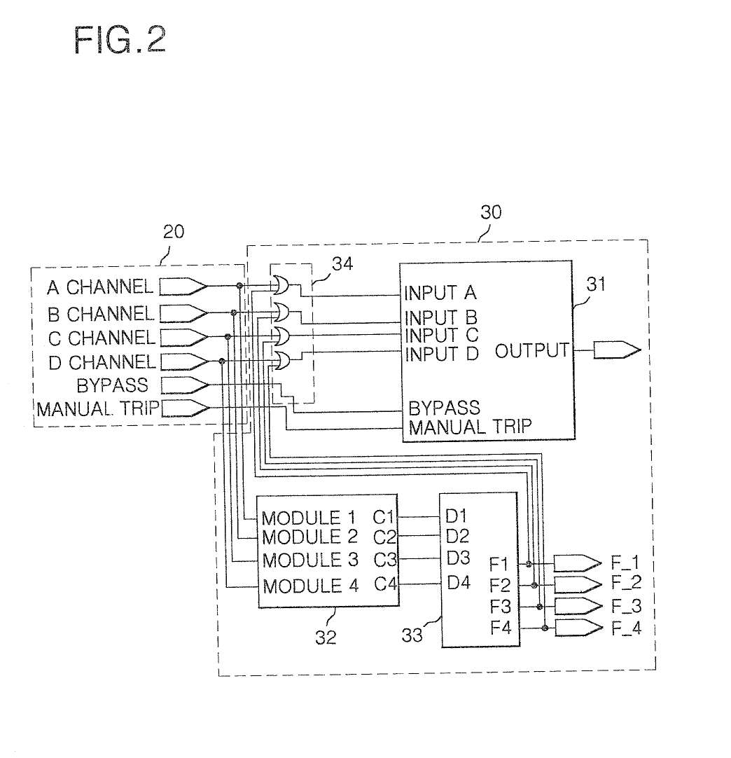

FIG. 2 schematically shows a failure detector and maintainer connected to a system board requiring reliability and safety for detecting a failure of the system board and maintaining the operation thereof according to the invention, and description thereof will be made as follows.

A failure detector and maintainer 30 is connected to a system board 20 for controlling the operation in the whole process, and is adapted to diagnose the failure and maintain the operation when the failure takes place.

The failure detector and maintainer 30 is connected to the system board 20 for detecting and judging signals from a number of channels of the system board 20 to transmit output signals. When the system board 20 has the failure in the operation, the failure detector and maintainer 30 maintains abnormal signals from the failed channels as normal signals to introduce the operation of the system board, which controls the operation of the overall system, in a safe manner even in failure so as to prevent loss of the overall system caused by abrupt operational stop of the system board 20.

In a detailed configuration, the failure detector and maintainer 30 is comprised of a voter 31, a comparator 32, a detector 33 and an OR gate 34.

The voter 31 is provided with a number of terminals having a parallel redundancy for the purpose of reliability reconsideration; an at least 2/4 simultaneous generation logic for recognizing high or low signals inputted from four channels A to D, and if at least two high signals are in the four input signals, confirming and outputting the corresponding input signals; and a manual trip terminal for separating the signals of the channels, when it is necessary, to repair the system board 20 when a failure occurs in the number of channels of the system board outputting malfunction signals, and allowing an operator to forcibly change the signals regardless of the output value of the voter 31.

A comparator 32, for detecting the abnormality of the system, compares the signals from the number of channels of the system board 20 to judge a channel which outputs the signal different from the remaining three channels as a failed channel. In other words, the comparator 32 outputs a signal judging that the channel outputting the signal inconsistent and different from the remaining signals as the failed channel. For example, if the channels A to C output the high signals and the channel D outputs the low signal in the four channels A to D, a signal is transmitted informing that the channel D is failed.

Meanwhile, in the case of a channel for generating a failure signal due to an instantaneous noise, an initialization signal is transmitted to cancel a failure detection signal and then the channel can be normally operated again.

The detector 33 detects the channel generating an abnormal signal inputted from the comparator 32, and executes a feedback of high or low signal the same as those of the other channels to the OR gate 34 in order to prevent the operational abnormality in the system board 20 caused by the abnormal signal of the corresponding failed channel.

The signal inputted in the OR gate 34 is transmitted to the voter 31 again to maintain the operation of the system board 20 even in failure. Meanwhile, when the system board 20 has the abnormality, the abnormality in the system board 20 can be informed through an alarm so that stop of the whole system process can be prevented and thus the generation of loss can be removed.

Therefore, upon detecting the failure of the channel in the system board, the signal is outwardly sent while being maintained active until the initialization signal is received by a latch and the like. In the case of the instantaneous noise, the initialization signal is sent to cancel the failure detection signal and then the channel can be normally operated again.

Also, the failure detector and maintainer 30 is provided as the form of a single chip such as EPLD, CPLD, FPGA and the like to reduce the number of components connected in series so that the failure rate thereof can be lowered and the reliability thereof can be raised.

Meanwhile, the safety by the OR gate 34 in the failure detector and maintainer 30 for diagnosing the failure of the system board 20 and maintaining the operation thereof according to the invention will be described as follows.

The reliability of a voter 31 part follows the reliability of a general 2/4 redundancy and thereby description thereof will be omitted herein. A derivation process will be omitted and only results will be expressed as follows:

P₀(t)=e^{-λt} Equation 1,

P_{FS}(t)=C−Ce^{-λt} Equation 2,

P_{FU}(t)=(1−C)−(1−C)e^{-λt} Equation 3, and

S(t)=P₀(t)+P_{FS}(t)=C+(1−C)e^{λt} Equation 4,

herein P₀(t) is set as a probability when the system board 20 is normally operated, P_{FS}(t) as a probability when the system board 20 has a safe failure and thus maintains the operation, and P_{FU}(t) as a probability when the system board 20 has an unsafe failure and thus malfunctions. Here, solutions can be obtained through derivation of differential equations based upon the Markov model.

Equation 1 indicates the reliability of a single channel system with the failure rate as a constant λ, and the safety of the system can be expressed as Equation 4 by adding the reliability (P₀(t)) to Equation 2 as the probability of safe failure.

In other word, the safety is applied if the system is designed by the detector 33 so as to be normally operated through the feedback of signal about the failed channel. If C is 1 (perfect) in Equation 4, S(∞) is 1 and the system has the perfect safety, and the safety converges to S(∞)=C if C is a constant. In this case, the OR gate 34 functions as C and is obviously larger than 0. Accordingly, the safety of the system is enhanced as a result.

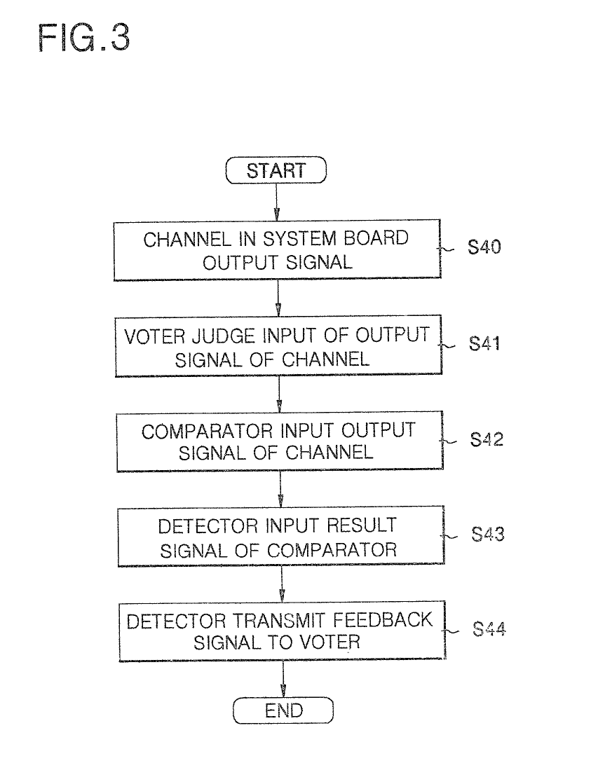

Meanwhile, FIG. 3 is a flow chart of the failure detector and maintainer 30 for detecting the failure of the system board and maintaining the operation thereof, and description thereof will be as follows.

When the signals from the channels A to D are received in input terminals A to D of the voter 31 in the failure detector and maintainer 30 while the system board 20 is being operated, if the at least two terminals have the high signals of the input signals, the voter 31 recognizes the corresponding signals and transmits the same to the output terminal (step S40 and S41).

Meanwhile, the signals from the channels A to D in the system board 20 are received in the voter 31 of the failure detector and maintainer 30 and simultaneously to the comparator 32 for diagnosing the failure of the system board 20 and maintaining the operation, and the comparator 32 compares the input signals and transmits a signal recognizing that the corresponding channel is failed if one channel transmits the signal different from other channels (step S42).

The comparator 33, for normalizing the signal of the abnormal channel terminal received from the comparator 32, inputs the high signal to the voter 31 through the OR gate 34 to prevent the malfunction even if the system board 20 is abnormal, thereby creating the reliability and safety to the important system used for controlling the overall process (step S44).

Meanwhile, a bypass terminal of the voter 31 functions to separate or bypass the signal under repair due to the failure of the system board 20, and the manual trip terminal allows an operator to forcibly change the output value in the operation signal regardless of the input.

As described hereinbefore, the present invention relates to the failure detector and maintainer 30 for diagnosing the failure and maintaining the operation through the connection to the system board 20 for controlling an important process. The failure detector and maintainer 30 compares the signals from the channels in the system board 20 to detect the failed channel in the system board 20 and executes the feedback of signal to the failed channel for output of the normal signal, and accordingly can maintain the normal operation, even if the system board 20 is failed, to prevent loss caused by the malfunction. Further, if the failure detector and maintainer 30 is constituted as the form of a single chip such as EPLD, CPLD and EPGA, the number of components can be reduced to enhance the reliability of hardware.

As described hereinbefore, the invention provides the failure detector and maintainer connected to the system board requiring the reliability and safety, in which the failure detector and maintainer can detect the failure of the system board in operation and prevent the malfunction due to the failure of the system board to maintain the operation thereof thereby preventing loss due to the malfunction of the system board controlling the whole process.

Further, the signal processing apparatus of the invention is constituted as the form of a chip such as EPLD, CPLD and the like to reduce the number of components connected in series thereby obtaining effects that the failure rate of hardware can be lowered and the reliability of the system board can be raised.

What is claimed is:

1. An apparatus for inspecting errors in a system board including a number of channels for controlling the overall operation of a system, comprising:
means for judging signals respectively received in the number of channels of the system board;
means for comparing the signals respectively received in the number of channels of the system board to output signals respectively informing if the channels are failed or not; and
means for respectively transmitting normal signals to the failed channels, which are respectively inputted by said comparing means, to maintain the operation of the system board.

2. An apparatus for inspecting errors in a system board according to claim 1, wherein said judging means, comparing means and maintaining means are provided as the form of a single chip.

3. An apparatus for inspecting errors in a system board according to claim 1, wherein said judging means comprises:
a bypass terminal for separating a signal of the failed channel when interruption of the signal is required due to repair of the failed channel in the system board; and
a manual trip terminal capable of forcibly changing the output value of said judging means to convert the operation.

4. An apparatus for inspecting errors in a system board according to claim 1, wherein said comparing means compares the input signals in the channels of the system board, and if a channel outputs a signal different from the other channels, outputs a signal informing that the channel outputting the different signal is failed.

5. An apparatus for inspecting errors in a system board according to claim 1, wherein said maintaining means comprises a logic circuit for transmitting an operation signal simultaneously with the signal outputted from the failed channel in the system board to normally maintain the operation of the system board upon receiving the failed channel informing signals.

6. An apparatus for inspecting errors in a system board according to claim 5, wherein said logic circuit is an OR gate.

7. A method of inspecting errors in a system board, comprising the following steps of:
receiving output signals in a voter from a number of channels of the system board;
receiving the output signals in a comparator simultaneously with the voter from the number of channels of the system board to compare the output signals;
comparing the output signals to output a signal informing that a channel outputting a signal different from the other channels is failed; and
transmitting and logic-combining a feedback signal simultaneously with the output signal of the failed channel to input a normal signal to the voter.
